(19) United States
(12) Patent Application Publication
(10) Pub. No.: US 2026/0297810 A1
(43) Pub. Date: Oct. 1, 2026

(54) SILICON SINGLE CRYSTAL MANUFACTURING METHOD, AND SILICON SINGLE CRYSTAL MANUFACTURING APPARATUS

(71) Applicant: SUMCO CORPORATION, Tokyo (JP)

(72) Inventors: Wataru SUGIMURA, Tokyo (JP); Ryusuke YOKOYAMA, Tokyo (JP); Hideki SAKAMOTO, Tokyo (JP); Naoki MATSUSHIMA, Tokyo (JP); Yu MURAMATSU, Tokyo (JP)

(73) Assignee: SUMCO CORPORATION, Tokyo (JP)

(21) Appl. No.: 19/479,090

(22) PCT Filed: Dec. 28, 2023
(86) PCT No.: PCT/JP2023/047291

§ 371 Date: Oct. 27, 2025

(30) Foreign Application Priority Data
Apr. 28, 2023 (JP) 2023-074578

(51) Int. Cl. C30B 30/04; C30B 15/10; C30B 15/14; C30B 15/20; C30B 15/30; C30B 29/06

(52) U.S. Cl. CPC C30B 30/04; C30B 15/10; C30B 15/14; C30B 15/20; C30B 15/305; C30B 29/06

(57) ABSTRACT

A monocrystalline-silicon-manufacturing method, using a monocrystalline-silicon-manufacturing apparatus, includes: generating a silicon melt by heating a rotating crucible while a heat-generation distribution of the heater is non-uniform; starting applying a horizontal magnetic field to the silicon melt; and growing the monocrystalline silicon. The monocrystalline-silicon-manufacturing apparatus includes: a cylindrical heater surrounding the crucible; and first-to-fourth support-electrodes supporting the heater, in which the heater includes first-to-fourth heat generators, the first support-electrode connects the first-and-second heat generators to a positive electrode of a power source, the second support-electrode connects the second-and-third heat generators to a negative electrode of the power source, the third support-electrode connects the third-and-fourth heat generator to the positive electrode, the fourth support-electrode connects the fourth-and-first heat generator to the negative electrode, at least one of the first-to-fourth support electrodes is a small-diameter support electrode having at least a portion smaller in thickness than remaining ones of the first-to-fourth support-electrodes.

### TECHNICAL FIELD

The present invention relates to a method of manufacturing monocrystalline silicon and a monocrystalline silicon manufacturing apparatus.

### BACKGROUND ART

The MCZ (Magnetic Field Applied Czochralski) method, in which a horizontal magnetic field is applied to silicon melt, is sometimes used as a method of manufacturing monocrystalline silicon. In a case where a horizontal magnetic field is applied to silicon melt by the MCZ method, a direction of a convection in a virtual plane perpendicular to an application direction of the horizontal magnetic field in the silicon melt may be either clockwise (hereinafter, occasionally referred to as “clockwise vortex mode”) or counterclockwise (hereinafter, occasionally referred to as “counterclockwise vortex mode”).

The formed convection mode is at random either the clockwise vortex mode or the counterclockwise vortex mode. Accordingly, an oxygen concentration incorporated into the monocrystalline silicon varies depending on the convection mode and furnace environments. In order to obtain monocrystalline silicon having a stable oxygen concentration, it is important to control the convection mode of the silicon melt during pulling up of the monocrystalline silicon. Various studies in consideration of this have been made for controlling the convection mode of the silicon melt in the crucible (see, for instance, Patent Literature 1).

Patent Literature 1 discloses a method in which a convection mode is fixed to either the clockwise vortex mode or the counterclockwise vortex mode by causing a thermal environment in a furnace of a manufacturing apparatus to be non-axisymmetric with respect to a center axis of a crucible, thus eliminating a variation in oxygen concentration attributed to the convection mode. As a specific method of the above, Patent Literature 1 discloses a method using a heating section in which a heat generation amount of a first heating region on one side in a right-and-left direction in a virtual plane perpendicular to an application direction of a horizontal magnetic field in silicon melt is set to a value different from a heat generation amount of a second heating region on the other side.

Patent Literature 1 discloses, as a method of making the heat generation amount of the first heating region different from that of the second heating region, a method of making a contact resistance value of a power supplying section that supplies power to a heat generator in the first heating region different from that in the second heating region.

Then, Patent Literature 1 discloses, as the method of making the contact resistance values different, a method of making a total number of electrical resistance adjustment members interposed between a terminal connected to the heat generator in the first heating region and an electrode different from that in the second heating region, a method of making a fastening force to fasten the terminal connected to the heat generator in the first heating region to the electrode different from that in the second heating region, and a method of making a material or thickness of an adhesive layer bonding the terminal connected to the heat generator in the first heating region to the electrode different from that in the second heating region.

Patent Literature 1 also discloses, as another method of making the heat generation amount of the first heating region different from that of the second heating region, a method of making at least one of a length or total number of slits provided in the first heating region different from that in the second heating region.

### CITATION LIST

### Patent Literature(s)

Patent Literature 1: JP 2022-102247 A

### SUMMARY OF THE INVENTION

### Problem(s) to be Solved by the Invention

However, for the method of making the contact resistance values different disclosed in Patent Literature 1, there is a possibility that in setting the contact resistance value to a desired value, the convection mode of the silicon melt changes from a desired state under an influence of an operation variation, a degradation of a member, or the like. Moreover, the method of making at least one of the length or total number of the slits different disclosed in Patent Literature 1 requires a heating section in a special shape.

An object of the invention is to provide a method of manufacturing monocrystalline silicon and a monocrystalline silicon manufacturing apparatus capable of manufacturing a monocrystalline silicon with a stable oxygen concentration without the necessity of considerably changing a typical apparatus configuration.

### Means for Solving the Problem(s)

According to an aspect of the invention, a method of manufacturing monocrystalline silicon, including pulling up a monocrystalline silicon while applying a horizontal magnetic field to a silicon melt, with use of a monocrystalline silicon manufacturing apparatus, in which the monocrystalline silicon manufacturing apparatus includes: a crucible in which the silicon melt is received; a heater formed in a cylindrical shape surrounding the crucible, the heater being disposed with a center axis of the cylindrical shape being coaxial with a center axis of the crucible; and a first support electrode, a second support electrode, a third support electrode, and a fourth support electrode each formed in a rod shape from a material with electrical conductive properties and supporting the heater, the heater including a first heat generator, a second heat generator, a third heat generator, and a fourth heat generator each having identical heat generation characteristics and being arranged in an outer peripheral direction of the crucible, the first support electrode connecting the first heat generator and the second heat generator to a positive electrode of a power source, the second support electrode connecting the second heat generator and the third heat generator to a negative electrode of the power source or a ground, the third support electrode connecting the third heat generator and the fourth heat generator to the positive electrode, the fourth support electrode connecting the fourth heat generator and the first heat generator to the negative electrode or the ground, at least one of the first support electrode, the second support electrode, the third support electrode, or the fourth support electrode being a small-diameter support electrode having at least a portion that is smaller in thickness than remaining ones of the first to fourth support electrodes, the method further including: generating the silicon melt by heating a silicon material in the rotating crucible while a heat generation distribution of the heater is non-uniform; starting applying the horizontal magnetic field to the silicon melt; and growing the monocrystalline silicon by pulling up a seed crystal immersed in the silicon melt after a convection direction of the silicon melt in a virtual plane perpendicular to a central magnetic field line of the horizontal magnetic field is fixed to one direction.

In the method of manufacturing monocrystalline silicon according to above aspect of the invention, it is preferable that the monocrystalline silicon manufacturing apparatus includes a heat insulator formed in a cylindrical shape surrounding the heater, the heat insulator being configured to provide a non-uniform heat removal distribution with respect to the heater.

In the method of manufacturing monocrystalline silicon according to above aspect of the invention, it is preferable that the heat insulator has uniform thermal conductivity throughout and is disposed with a center axis of the heat insulator not being coaxial with the center axis of the crucible.

In the method of manufacturing monocrystalline silicon according to above aspect of the invention, it is preferable that the heat insulator is configured such that thermal conductivity of one portion differs from that of other portions and is disposed with a center axis of the heat insulator being coaxial with the center axis of the crucible.

In the method of manufacturing monocrystalline silicon according to above aspect of the invention, it is preferable that when a rotation speed of the crucible during application of the horizontal magnetic field to the silicon melt is defined as R (rpm), and a time elapsed from the start of the application of the horizontal magnetic field until the horizontal magnetic field with a magnetic field intensity sufficient to fix the convection direction acts on the silicon melt is defined as T (minute), the first support electrode, the second support electrode, the third support electrode, the fourth support electrode, and the heat insulator are configured such that: a maximum heating temperature position at which a heating temperature applied to the crucible is highest in plan view is located on a side opposite to a rotation direction of the crucible with respect to a first horizontal virtual line, the first horizontal virtual line being perpendicular to the central magnetic field line and including the center axis of the crucible; and an angle θ (degree) made by a second horizontal virtual line and the first horizontal virtual line satisfies Equation (1) below, the second horizontal virtual line connecting the center axis of the crucible and the maximum heating temperature position,

$$θ = 360 \times R \times T . \qquad ( 1 )$$

According to another aspect of the invention, a monocrystalline silicon manufacturing apparatus configured to pull up monocrystalline silicon while applying a horizontal magnetic field to a silicon melt, the monocrystalline silicon manufacturing apparatus including: a crucible in which the silicon melt is received; a heater formed in a cylindrical shape surrounding the crucible, the heater being disposed with a center axis of the cylindrical shape being coaxial with a center axis of the crucible; and a first support electrode, a second support electrode, a third support electrode, and a fourth support electrode each formed in a rod shape from a material with electrical conductive properties and supporting the heater, in which the heater includes a first heat generator, a second heat generator, a third heat generator, and a fourth heat generator each having identical heat generation characteristics and being arranged in an outer peripheral direction of the crucible, the first support electrode connects the first heat generator and the second heat generator to a positive electrode of a power source, the second support electrode connects the second heat generator and the third heat generator to a negative electrode of the power source or a ground, the third support electrode connects the third heat generator and the fourth heat generator to the positive electrode, the fourth support electrode connects the fourth heat generator and the first heat generator to the negative electrode or the ground, and at least one of the first support electrode, the second support electrode, the third support electrode, or the fourth support electrode is a small-diameter support electrode having at least a portion that is smaller in thickness than remaining ones of the first to fourth support electrodes.

In the monocrystalline silicon manufacturing apparatus according to above aspect of the invention, it is preferable that the monocrystalline silicon manufacturing apparatus includes a heat insulator formed in a cylindrical shape surrounding the heater, the heat insulator being configured to provide a non-uniform heat removal distribution with respect to the heater.

In the monocrystalline silicon manufacturing apparatus according to above aspect of the invention, it is preferable that the heat insulator has uniform thermal conductivity throughout and is disposed with a center axis of the heat insulator not being coaxial with the center axis of the crucible.

In the monocrystalline silicon manufacturing apparatus according to above aspect of the invention, it is preferable that the heat insulator is configured such that thermal conductivity of one portion differs from that of other portions and is disposed with a center axis of the heat insulator being coaxial with the center axis of the crucible.

In the monocrystalline silicon manufacturing apparatus according to above aspect of the invention, it is preferable that when a rotation speed of the crucible during application of the horizontal magnetic field to the silicon melt is defined as R (rpm), and a time elapsed from the start of the application of the horizontal magnetic field until the horizontal magnetic field with a magnetic field intensity sufficient to fix a convection direction acts on the silicon melt is defined as T (minute), the first support electrode, the second support electrode, the third support electrode, the fourth support electrode, and the heat insulator are configured such that: a maximum heating temperature position at which a heating temperature applied to the crucible is highest in plan view is located on a side opposite to a rotation direction of the crucible with respect to a first horizontal virtual line, the first horizontal virtual line being perpendicular to the central magnetic field line of the horizontal magnetic field and including the center axis of the crucible; and an angle θ (degree) made by a second horizontal virtual line and the first horizontal virtual line satisfies Equation (2) below, the second horizontal virtual line connecting the center axis of the crucible and the maximum heating temperature position,

$$θ = 360 \times R \times T . \qquad ( 2 )$$

### BRIEF DESCRIPTION OF DRAWINGS

FIG. 1 is a longitudinal sectional view illustrating a schematic configuration of a monocrystalline silicon manufacturing apparatus according to an exemplary embodiment.

FIG. 2 is a plan schematic diagram illustrating a heater, a heat insulator, and a magnetic-field applying section according to the exemplary embodiment.

FIG. 3 is a perspective view of the heater according to the exemplary embodiment.

FIG. 4 is a side view illustrating a low-resistance support electrode and a high-resistance support electrode according to the exemplary embodiment.

FIG. 5 is an equivalent circuit diagram of the heater and a power supplying section according to the exemplary embodiment.

FIG. 6A is a diagram for explaining a favorable configuration of first to fourth support electrodes and the heat insulator according to the exemplary embodiment and also a plan view illustrating a maximum heating temperature position.

FIG. 6B is a diagram for explaining the favorable configuration of the first to fourth support electrodes and the heat insulator according to the exemplary embodiment and also a graph illustrating a relationship between elapsed time from the start of application of a horizontal magnetic field and a magnetic field intensity.

FIG. 7 is a block diagram of a relevant part of the monocrystalline silicon manufacturing apparatus according to the exemplary embodiment.

FIG. 8 is a flowchart illustrating a method of manufacturing monocrystalline silicon according to the exemplary embodiment.

FIG. 9 is a plan view illustrating a position of a melt high-temperature region according to Example.

FIG. 10A is a graph illustrating an occurrence rate of each of convection modes in Comparative Example according to Example and Examples 1 to 8.

FIG. 10B is a graph illustrating an occurrence rate of each of the convection modes in Comparative Example according to Example and Examples 9 to 16.

### DESCRIPTION OF EMBODIMENT(S)

### Exemplary Embodiment

### Configuration of Monocrystalline Silicon Manufacturing Apparatus

First, description will be made on a configuration of a monocrystalline silicon manufacturing apparatus according to an exemplary embodiment of the invention.

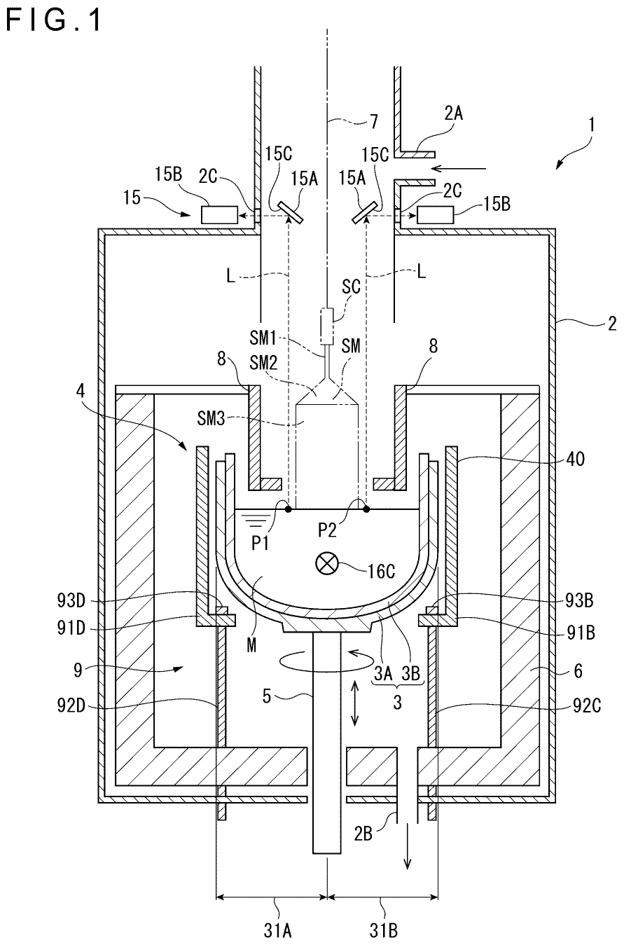

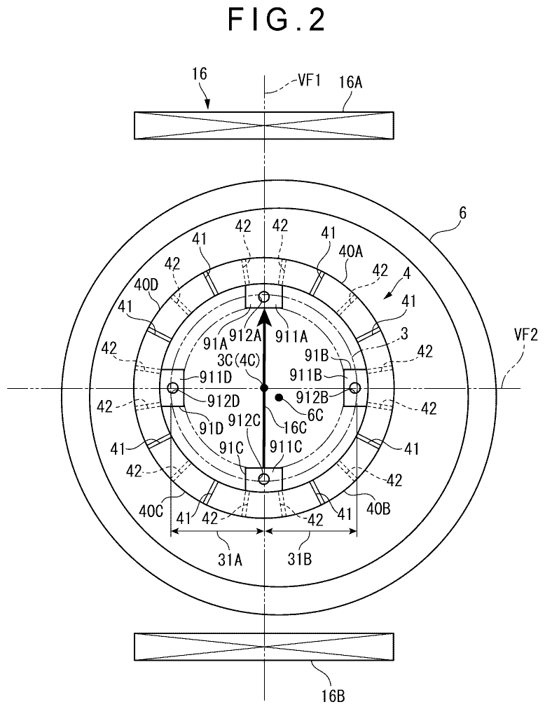

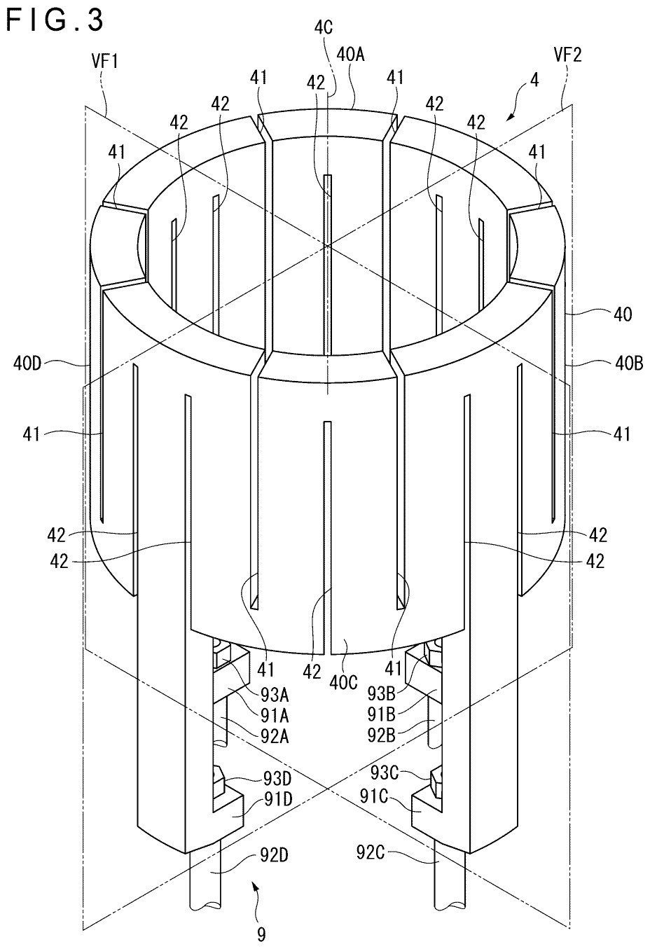

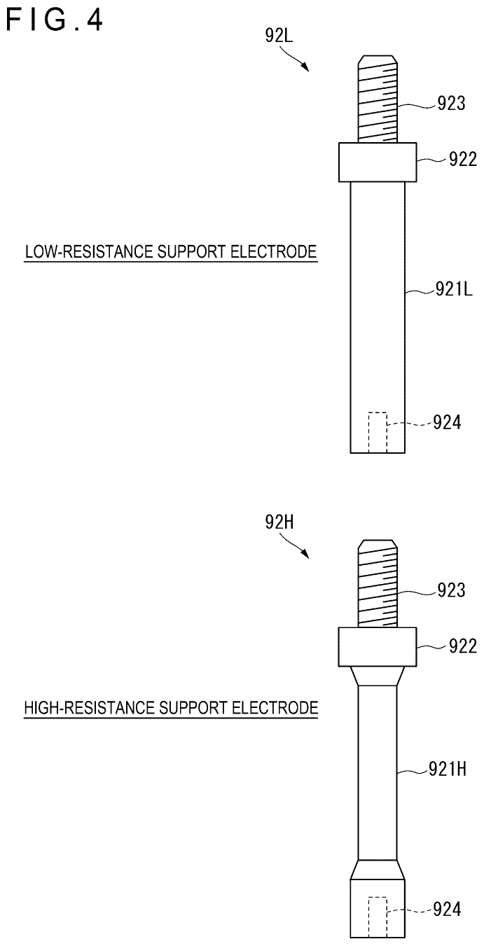

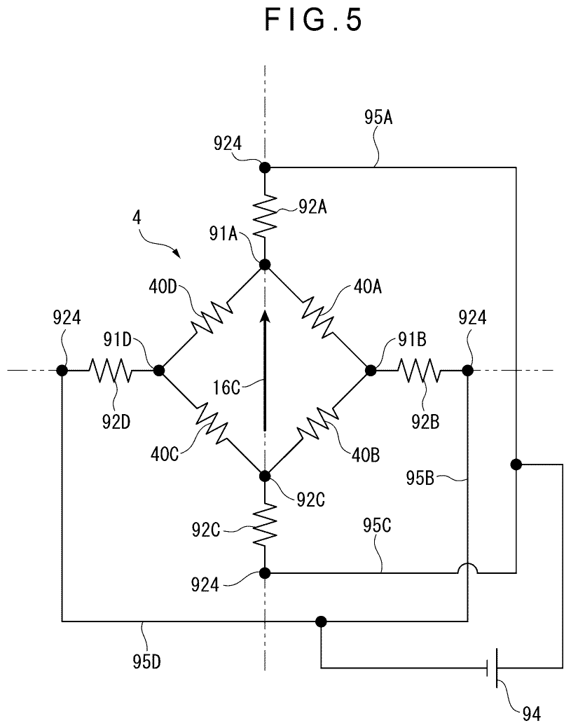

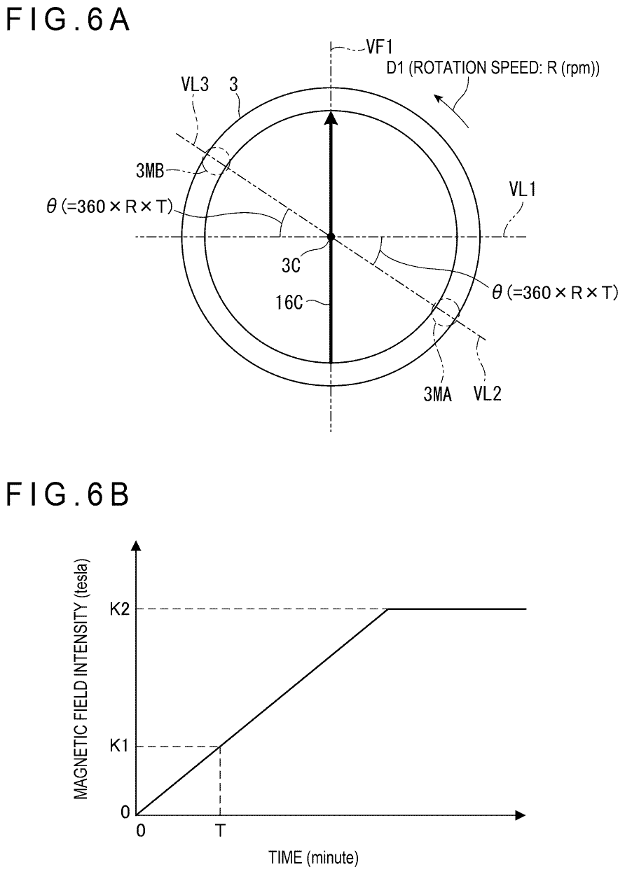

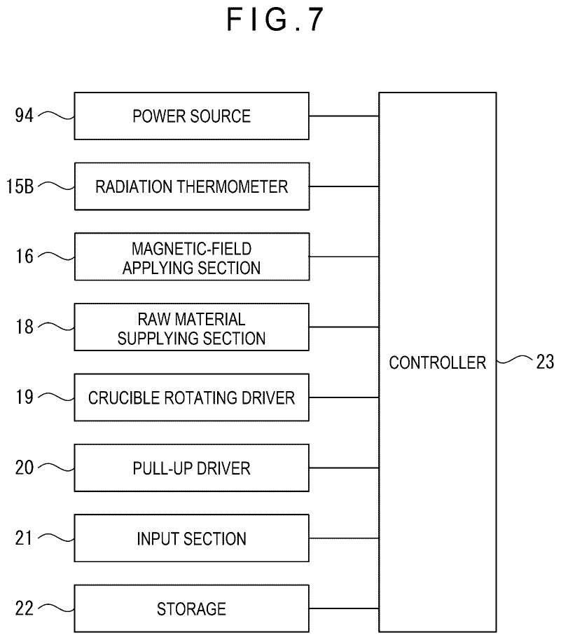

FIG. 1 is a longitudinal sectional view illustrating a schematic configuration of the monocrystalline silicon manufacturing apparatus. FIG. 2 is a plan schematic diagram illustrating a heater, a heat insulator, and a magnetic-field applying section. FIG. 3 is a perspective view of the heater. FIG. 4 is a side view illustrating a low-resistance support electrode and a high-resistance support electrode. FIG. 5 is an equivalent circuit diagram of the heater and a power supplying section. FIG. 6A is a diagram for explaining a favorable configuration of first to fourth support electrodes and the heat insulator and also a plan view illustrating a maximum heating temperature position. FIG. 6B is a diagram for explaining the favorable configuration of the first to fourth support electrodes and the heat insulator and also a graph illustrating a relationship between elapsed time from the start of application of a horizontal magnetic field and a magnetic field intensity. FIG. 7 is a block diagram of a relevant part of the monocrystalline silicon manufacturing apparatus.

A monocrystalline silicon manufacturing apparatus 1 illustrated in FIG. 1, which is an apparatus to manufacture a monocrystalline silicon SM by the MCZ method, pulls up monocrystalline silicon SM including a neck SM1, a shoulder SM2, a straight body SM3, and a non-illustrated tail while applying a horizontal magnetic field to a silicon melt M. The monocrystalline silicon manufacturing apparatus 1 includes a chamber 2 forming an outer enclosure, a crucible 3 disposed at a central portion of the chamber 2, a heater 4 disposed around the crucible 3, and a temperature measuring section 15.

The crucible 3 has a double structure including an outer graphite crucible 3A and an inner quartz crucible 3B. The silicon melt M is to be received in the quartz crucible 3B. The graphite crucible 3A and the quartz crucible 3B, which are in a form of a bottomed cylindrical container, are circular in plan view as viewed from vertically above. The crucible 3 is fixed to an upper end portion of a support shaft 5 capable of rotation and up-and-down movement.

The heater 4 is a graphite heater formed substantially in a cylindrical shape and disposed around the crucible 3. A cylindrical heat insulator 6 is provided outside the heater 4 along an inner surface of the chamber 2. The heat insulator 6 is configured such that thermal conductivity is uniform throughout.

A pull-up shaft 7 is disposed coaxially with the support shaft 5 above the crucible 3. The pull-up shaft 7 is provided by a wire or the like. A seed crystal SC is attached to a lower end of the pull-up shaft 7.

A tubular heat shield 8 that surrounds the growing monocrystalline silicon SM above the silicon melt M in the crucible 3 is disposed in the chamber 2.

The heat shield 8 shields the growing monocrystalline silicon SM from radiant heat from the silicon melt M, a side wall of the crucible 3, and the heater to suppress a rise in temperature of the monocrystalline silicon SM.

An upper portion of the chamber 2 is provided with a gas inlet 2A, through which an inert gas such as argon gas is to be introduced into the chamber 2. A lower portion of the chamber 2 is provided with a gas outlet 2B, through which the gas in the chamber 2 is to be sucked and discharged by driving a non-illustrated vacuum pump.

The temperature measuring section 15 measures temperatures at a first measurement point P1 and a second measurement point P2. Radial positions of the first measurement point P1 and the second measurement point P2 are between an outer peripheral surface of a monocrystalline silicon SM to be grown and an inner peripheral surface of an opening of the heat shield 8. As described later, it is possible to confirm a convection mode of the silicon melt M by measuring the temperatures at the first measurement point P1 and the second measurement point P2. For instance, in a case where a direction of a convection of the silicon melt M is fixed to a clockwise direction in FIG. 1 by heating the silicon melt M with the heater 4, in other words, in a case where the convection mode of the silicon melt M becomes a clockwise vortex mode, a measurement temperature at the first measurement point P1 exceeds a measurement temperature at the second measurement point P2. In contrast, in a case where the direction of the convection of the silicon melt M is fixed to a counterclockwise direction by heating the silicon melt M with the heater 4, in other words, in a case where the convection mode becomes a counterclockwise vortex mode, the measurement temperature at the first measurement point P1 falls less than the measurement temperature at the second measurement point P2.

The temperature measuring section 15 includes a pair of reflectors 15A and a pair of radiation thermometers 15B.

The reflectors 15A are installed inside the chamber 2. It is preferable that the reflectors 15A be installed such that an angle made by a reflection surface 15C and a horizontal plane falls within a range from 40 degrees to 50 degrees.

The radiation thermometers 15B are installed outside the chamber 2. The radiation thermometers 15B measure the temperatures at the first measurement point P1 and the second measurement point P2 in a non-contact manner by receiving radiation light L entering through a quartz window 2c (see FIG. 1) provided in the chamber 2.

As illustrated in FIG. 2, the monocrystalline silicon manufacturing apparatus 1 further includes a magnetic-field applying section 16.

The magnetic-field applying section 16 includes a first magnetic body 16A and a second magnetic body 16B, each of which is provided by a magnet coil. The first magnetic body 16A and the second magnetic body 16B are disposed outside the chamber 2 so as to face each other with the crucible 3 interposed therebetween. The magnetic-field applying section 16 applies a horizontal magnetic field such that, in plan view, a central magnetic field line 16C passing through a coil center axis intersects a center axis 3C of the crucible 3 (hereinafter, occasionally referred to as “crucible center axis 3C”) and is in alignment with a direction from the second magnetic body 16B toward the first magnetic body 16A (an upward direction indicated by an arrow representing the central magnetic field line 16C in FIG. 2, which is a direction from the near side toward the far side of the paper in FIG. 1).

The heater 4 is disposed such that a center axis 4C thereof (hereinafter, occasionally referred to as “heater center axis 4C”) is coaxial with the crucible center axis 3C. In contrast, the heat insulator 6 is disposed such that a center axis 6C thereof (hereinafter, occasionally referred to as “heat insulator center axis 6C”) is not coaxial with either the crucible center axis 3C or the heater center axis 4C. In other words, the heater 4 is disposed such that a gap between the heater 4 and the crucible 3 is uniform in a circumferential direction of the crucible 3. Moreover, the heat insulator 6 is disposed such that a gap between the heat insulator 6 and the heater 4 is non-uniform in a circumferential direction of the heater 4. Such an arrangement of the heater 4 and the heat insulator 6 causes a heat removal distribution from the heater 4 by the heat insulator 6 to be non-uniform in the circumferential direction of the crucible 3.

As illustrated in FIG. 2 and FIG. 3, the heater 4 includes a heat generator 40, which is a graphite heater formed in a cylindrical shape. The heat generator 40 is formed with a uniform thickness throughout in the circumferential direction. The heat generator 40 has a plurality of upper slits 41 extending downward from an upper end and a plurality of lower slits 42 extending upward from a lower end. The upper slits 41 and the lower slits 42 are alternately formed side by side in the circumferential direction of the heat generator 40. Widths of the upper slits 41 and the lower slits 42 are equal to each other and depths of cut thereof along an up-and-down direction are also equal to each other. Moreover, distances between the upper slits 41 and the lower slits 42 are also equal throughout an entire circumference of the heater 4.

The heat generator 40 is divided into four by a first vertical virtual plane VF1 and a second vertical virtual plane VF2, which include the heater center axis 4C and are perpendicular to each other, so that the heat generator 40 includes a first heat generator 40A, a second heat generator 40B, a third heat generator 40C, and a fourth heat generator 40D that have the same heat generation characteristics. The same heat generation characteristics mean that the same portion generates heat when the same amount of power is supplied.

The first heat generator 40A to the fourth heat generator 40D are equal in total number of the upper slits 41 and the lower slits 42. In the exemplary embodiment, the first heat generator 40A to the fourth heat generator 40D are each formed with two of the upper slits 41 and three of the lower slits 42, for a total of five slits per heat generator.

Accordingly, resistance values of the first heat generator 40A to the fourth heat generator 40D having the same shape are the same.

The heater 4 is disposed such that the heater center axis 4C and the crucible center axis 3C are coaxial with each other and the central magnetic field line 16C overlaps the first vertical virtual plane VF1 in plan view. It should be noted that the heater 4 may be disposed such that the central magnetic field line 16C does not overlap the first vertical virtual plane VF1 in plan view.

The monocrystalline silicon manufacturing apparatus 1 includes a power supplying section 9 that supplies power to the heat generator 40. The power supplying section 9 includes a first terminal 91A, a second terminal 91B, a third terminal 91C, and a fourth terminal 91D, a first support electrode 92A, a second support electrode 92B, a third support electrode 92C, and a fourth support electrode 92D, and four nuts 93A, 93B, 93C, 93D. The first terminal 91A to the fourth terminal 91D are arranged at 90-degree intervals along the circumferential direction of the heat generator 40.

The first terminal 91A to the fourth terminal 91D each extend downward from a lower end of a portion delimited by two of the lower slits 42 of the heat generator 40 and integrally formed with the heat generator 40. Moreover, the first terminal 91A to the fourth terminal 91D include connecting portions 911A to 911D bent inward at a right angle from lower ends thereof, respectively, and the connecting portions 911A to 911D are formed with through holes 912A to 912D.

In other words, the heater 4 is provided by a graphite heater including the cylindrical heat generator 40, which is a heater element, and the first terminal 91A to the fourth terminal 91D, which are heater legs, and the heat generator and the first terminal 91A to the fourth terminal 91D are integrally molded.

As illustrated in FIG. 3, the first support electrode 92A to the fourth support electrode 92D are rod-shaped carbon electrodes with electrical conductive properties. One or more and not more than three of the first support electrode 92A to the fourth support electrode 92D each include a low-resistance support electrode 92L illustrated in the upper drawing in FIG. 4 and the rest of the support electrodes each include a high-resistance support electrode 92H, which is a small-diameter support electrode illustrated in the lower drawing in FIG. 4.

The low-resistance support electrode 92L includes an electrode body 921L, a clamping section 922, a male threaded section 923, and a power source connecting section 924. The electrode body 921L is formed in a columnar shape. The clamping section 922 is formed in a columnar shape larger in diameter and lower in height than the electrode body 921L and is provided at one end in an axial direction of the electrode body 921L. The male threaded section 923 is provided extending from the clamping section 922 to the opposite side of the electrode body 921L. The power source connecting section 924 is provided at the opposite end in the axial direction of the electrode body 921L.

The high-resistance support electrode 92H is a small-diameter electrode body 921H in place of the electrode body 921L. The small-diameter electrode body 921H is formed substantially in a columnar shape that is at least partially smaller in diameter than the electrode body 921L and is configured such that a resistance value of the high-resistance support electrode 92H is higher than a resistance value of the low-resistance support electrode 92L. In terms of supporting the heater 4, a diameter of the thinnest part of the small-diameter electrode body 921H is preferably 50 mm or more.

As is well known, it is possible to set the resistance values of the low-resistance support electrode 92L and the high-resistance support electrode 92H to desired values by adjusting the diameters or lengths of the electrode body 921L and the small-diameter electrode body 921H.

Carbon nuts 93A to 93D are screwed onto male threaded portions 923 inserted through through holes 912A to 912D of terminals 91A to 91D, and the terminals 91A to 91D are clamped between the nuts 93A to 93D and the clamping section 922. With this configuration, the first to fourth support electrodes 92A to 92D, each formed of either the high-resistance support electrode 92H or the low-resistance support electrode 92L, are electrically connected to the terminals 91A to 91D and support the heater 4.

As illustrated in FIG. 5, the power supplying section 9 further includes a power source 94, a first anode wiring 95A, a first cathode wiring 95B, a second anode wiring 95C, and a second cathode wiring 95D.

One ends of the respective first and second anode wirings 95A, 95C are connected to the power source connecting sections 924 of the first and third support electrodes 92A, 92C through, for instance, non-illustrated connectors, and the opposite ends thereof are connected to an anode of the power source 94. One ends of the respective first and second cathode wirings 95B, 95D are connected to the power source connecting section 924 of the second and fourth support electrodes 92B, 92D through, for instance, non-illustrated connectors and the opposite ends thereof are connected to a cathode of the power source 94. It should be noted that the opposite ends of the first and second cathode wirings 95B, 95D may be connected to a ground.

In the configuration of the heater 4 and the power supplying section 9 as illustrated in FIG. 5, for instance, the fourth support electrode 92D may be the high-resistance support electrode 92H while the first support electrode 92A to third support electrode 92C may be the low-resistance support electrodes 92L. In this case, the current flowing from the power source 94 to the fourth support electrode 92D is smaller than the current flowing from the power source 94 to the second support electrode 92B. As a result, the first and second heat generators 40A, 40B generate heat at a higher temperature than the third and fourth heat generators 40C, 40D, which results in a non-uniform heat generation distribution in the circumferential direction of the crucible 3.

As seen from the above, one or more and not more than three of the first support electrode 92A to the fourth support electrode 92D are each the high-resistance support electrode 92H, which makes it possible to set a position at which a heating temperature for the crucible 3 becomes the highest in plan view (hereinafter, occasionally referred to as “maximum heating temperature position”) to a desired position.

Moreover, as described above, the heat insulator 6 is disposed such that the heat insulator center axis 6C is not coaxial with either the crucible center axis 3C or the heater center axis 4C and therefore the heat removal distribution from the heater 4 is not uniform in the circumferential direction of the crucible 3.

Accordingly, it is possible to more finely adjust a maximum heating temperature applied to the crucible 3 and the maximum heating temperature position by adjusting a position of the high-resistance support electrode 92H with respect to the crucible 3 and a position at which the gap between the heat insulator 6 and the heater 4 is the smallest.

It should be noted that hereinafter, a state in which the crucible 3 is heated such that the maximum heating temperature position is formed by adjusting the heat generation distribution of the heater 4 and the heat removal distribution from the heater 4 by the heat insulator 6 is referred to as a “non-uniform heating condition.” In contrast, a state in which the crucible 3 is heated such that the maximum heating temperature position is not formed, in other words, a state in which the crucible 3 is heated such that a heating distribution for the crucible 3 is uniform in the circumferential direction of the crucible 3, is occasionally referred to as “uniform heating state.”

Here, since a thermal conductivity of the crucible 3 is large and a thickness of the entire crucible 3 is uniform, a temperature of the crucible 3 heated in the non-uniform heating state by the heater 4 continuously changes. Thus, within the silicon melt M, a region heated to the highest temperature (hereinafter, occasionally referred to as “melt high-temperature region”) at the maximum heating temperature position and a region heated to the lowest temperature (hereinafter, occasionally referred to as “melt low-temperature region”) are opposed to each other across a center of the silicon melt M.

More preferably, positions of the high-resistance support electrode 92H and the heat insulator 6 with respect to the crucible 3 are set such that a difference in melt temperature obtained by subtracting a temperature of the melt low-temperature region from a temperature of the melt high-temperature region is preferably 3 degrees C. or more, more preferably 5 degrees C. or more. This is because a difference in melt temperature of 3 degrees C. or more makes the convection mode likely to be fixed to one mode irrespective of an application timing of the horizontal magnetic field and a difference in melt temperature of 5 degrees C. or more makes the convection mode more likely to be fixed to one mode irrespective of the application timing of the horizontal magnetic field.

It is preferable that the first support electrode 92A to the fourth support electrode 92D and the heat insulator 6 be configured such that heating amounts for a first portion 31A and a second portion 31B of the crucible 3, which are located opposite each other across the first vertical virtual plane VF1 illustrated in FIG. 1 and FIG. 2, differ from each other. It is more preferable that as illustrated in FIG. 6A, the first support electrode 92A to the fourth support electrode 92D and the heat insulator 6 be configured such that: a maximum heating temperature position 3MA, at which the heating temperature for the crucible 3 is the highest in plan view, is located on a right side with respect to the crucible center axis 3C and located on a side opposite to a rotation direction D1 of the crucible 3 with respect to a first horizontal virtual line VL1, which is perpendicular to the central magnetic field line 16C and includes the crucible center axis 3C; and an angle θ (degree) made by a second horizontal virtual line VL2, which connects the crucible center axis 3C and the maximum heating temperature position 3MA, and the first horizontal virtual line VL1 satisfies Equation (3) below.

Alternatively, it is more preferable that the first support electrode 92A to the fourth support electrode 92D and the heat insulator 6 be configured such that: a maximum heating temperature position 3MB, at which the heating temperature for the crucible 3 is the highest in plan view, is located on a left side with respect to the crucible center axis 3C and located on a side opposite to the rotation direction D1 with respect to the first horizontal virtual line VL1; and the angle θ (degree) made by a second horizontal virtual line VL3, which connects the crucible center axis 3C and the maximum heating temperature position 3MB, and the first horizontal virtual line VL1 satisfies Equation (3) below.

$$θ = 360 \times R \times T . \qquad ( 3 )$$

It should be noted that in Equation (3), R denotes a rotation speed (rpm) of the crucible 3 during the application of the horizontal magnetic field to the silicon melt M. T denotes time (minute) elapsed before the horizontal magnetic field with a magnetic field intensity sufficient to fix a convection direction (hereinafter, occasionally referred to as “convection direction fixing magnetic field intensity K1”) acts on the silicon melt M after the application of the horizontal magnetic field is started. The convection direction fixing magnetic field intensity K1 is within a range from 0.05 tesla (500 gauss) to 0.15 tesla (1500 gauss).

Here, a description will be given of a reason why the first support electrode 92A to the fourth support electrode 92D and the heat insulator 6 are configured such that the maximum heating temperature positions 3MA, 3MB are located as illustrated in FIG. 6A.

If the crucible 3 is heated in the uniform heating state, the silicon melt M in the crucible 3 is uniformly heated throughout in the circumferential direction of the crucible 3.

In this case, a convection moving upward near a side surface of the crucible 3 and moving downward near a middle thereof occurs in the silicon melt M. In a state where no horizontal magnetic field is applied to the silicon melt M, a position of the downward flow may change at random to be offset from the center of the crucible 3 due to the unstableness of the convection.

When the horizontal magnetic field is started to be applied to the silicon melt M in such a state in order that the magnetic field intensity reaches a predetermined magnetic field intensity K2, a magnitude of the magnetic field acting on the silicon melt M increases in proportion to elapsed time after the start of application as illustrated in FIG. 6B. Then, when the horizontal magnetic field with the convection direction fixing magnetic field intensity K1 acts on the silicon melt M, a rotation of the downward flow in the rotation direction D1 is restricted and, eventually, a direction of the convection in a virtual plane perpendicular to an application direction of the horizontal magnetic field is fixed.

In a case where the crucible 3 is heated in the uniform heating state in this manner, the horizontal magnetic field is applied in a state in which the position of the downward flow is changing at random, so that the convection mode becomes the clockwise vortex mode or the counterclockwise vortex mode depending on the application timing.

In contrast, when the crucible 3 is heated in the non-uniform heating state, an upward flow stably occurs in the silicon melt M on the right side in the crucible 3 while a downward flow stably occurs on the left side in the crucible 3, or an upward flow stably occurs on the left side in the crucible 3 while a downward flow stably occurs on the right side in the crucible 3 even in a state where no horizontal magnetic field is applied to the silicon melt M, so that the position of the downward flow does not change at random unlike in the case where the crucible 3 is heated in the uniform heating state.

Moreover, the melt high-temperature region rotates in the rotation direction D1 with a rotation of the crucible 3 at a rotation speed R (rpm). In other words, a region in which the upward flow occurs in the silicon melt M moves in the rotation direction D1 at the rotation speed R (rpm) from near the maximum heating temperature positions 3MA, 3MB.

Since the maximum heating temperature position 3MA is set such that Equation (3) above is satisfied as described above, when the horizontal magnetic field with the convection direction fixing magnetic field intensity K1 acts on the silicon melt M after the elapse of T minutes after the application of the horizontal magnetic field is started, a rotation of the upward flow in the rotation direction D1 is restricted with the melt high-temperature region overlapping the first horizontal virtual line VL1 in plan view and, eventually, the convection is fixed counterclockwise to enter the counterclockwise vortex mode irrespective of the application timing of the horizontal magnetic field. Since the maximum heating temperature position 3MB is also set such that Equation (3) above is satisfied, when the horizontal magnetic field with the convection direction fixing magnetic field intensity K1 acts on the silicon melt M after the elapse of T minutes after the application of the horizontal magnetic field is started, a rotation of the upward flow in the rotation direction D1 is restricted with the melt high-temperature region overlapping the first horizontal virtual line VL1 in plan view and, eventually, the convection is fixed clockwise to enter the clockwise vortex mode irrespective of the application timing of the horizontal magnetic field.

As seen from the above, it is possible to stably cause the counterclockwise vortex mode or the clockwise vortex mode to occur by causing the horizontal magnetic field with the convection direction fixing magnetic field intensity K1 to act on the silicon melt M with the melt high-temperature region overlapping the first horizontal virtual line VL1 as compared with in a case where the horizontal magnetic field with the convection direction fixing magnetic field intensity K1 is caused to act on the silicon melt M with the melt high-temperature region not overlapping the first horizontal virtual line VL1.

As illustrated in FIG. 7, the monocrystalline silicon manufacturing apparatus 1 further includes a raw material supplying section 18, a crucible rotating driver 19, a pull-up driver 20, an input section 21, a storage 22, and a controller 23. The power source 94, the radiation thermometers 15B, the magnetic-field applying section 16, the raw material supplying section 18, the crucible rotating driver 19, the pull-up driver 20, the input section 21, and the storage 22 are connected to the controller 23 so as to be capable of transmitting and receiving various types of information.

The power source 94 supplies power to the heat generator 40 via the power supplying section 9 on the basis of control by the controller 23.

The radiation thermometers 15B output a signal corresponding to a measurement result to the controller 23.

The magnetic-field applying section 16 applies a horizontal magnetic field with a predetermined intensity to the silicon melt M on the basis of control by the controller 23.

The raw material supplying section 18 loads a silicon material into the crucible 3 on the basis of control by the controller 23.

The crucible rotating driver 19 causes the crucible 3 to rotate in a predetermined direction at a predetermined speed on the basis of control by the controller 23.

The pull-up driver 20 causes the pull-up shaft 7 to move up and down on the basis of control by the controller 23. The pull-up driver 20 also causes the pull-up shaft 7 to rotate in the opposite direction to or the same direction as a rotation direction of the support shaft 5 at a predetermined speed on the basis of control by the controller 23.

The input section 21 includes, for instance, a touch panel or a physical button. The input section 21 is used for an input operation of a variety of settings and outputs a signal corresponding to the input operation to the controller 23.

The storage 22 is a known storage device such as an HDD (Hard Disk Drive). The storage 22 stores a variety of information required for control of pulling up the monocrystalline silicon SM.

The controller 23 includes a CPU (Central Processing Unit). The controller 23 controls the pulling-up of the monocrystalline silicon SM by the CPU executing a program stored in the storage 22.

### Method of Manufacturing Monocrystalline Silicon

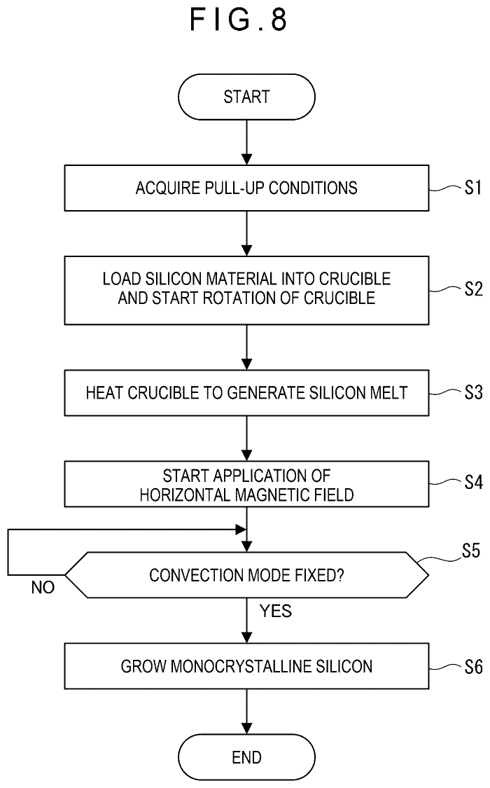

Next, a description will be given of a method of manufacturing the monocrystalline silicon SM using the monocrystalline silicon manufacturing apparatus 1. FIG. 8 is a flowchart illustrating the method of manufacturing monocrystalline silicon. It should be noted that in the exemplary embodiment, a description will be given of a case where the first support electrode 92A to the fourth support electrode 92D and the heat insulator 6 are configured such that the maximum heating temperature position is the maximum heating temperature position 3MA as illustrated in FIG. 6A.

First, an operator operates the input section 21 to input pull-up conditions for the monocrystalline silicon SM, which is a target to be manufactured.

The controller 23 acquires the inputted pull-up conditions as illustrated in FIG. 8 (Step S1).

After this, the controller 23 performs a process of manufacturing the monocrystalline silicon SM on the basis of the acquired pull-up conditions.

Specifically, in a state where the inside of the chamber 2 is maintained in an inert gas atmosphere under reduced pressure, the heater 4 is turned off (no power is supplied to the heater 4), and no horizontal magnetic field is applied, the controller 23 controls the raw material supplying section 18 to load the silicon material into the crucible 3 and then controls the crucible rotating driver 19 to cause the crucible 3 to rotate in the rotation direction D1 at the rotation speed R (Step S2).

Next, the controller 23 controls the power source 94 to cause the heat generator 40 of the heater 4 to heat the crucible 3 in the non-uniform heating state, melting the silicon material to generate the silicon melt M (Step S3: a silicon melt generating step). When all the silicon material is molten in Step S3, a region in which an upward flow occurs in the silicon melt M moves in the rotation direction D1 at the rotation speed R (rpm) from a position near the maximum heating temperature position 3MA.

After this, the controller 23 controls the magnetic-field applying section 16 to start applying the horizontal magnetic field to the silicon melt M so that the magnetic field intensity reaches the predetermined magnetic field intensity K2 (for instance, 0.3 tesla) (Step S4: a magnetic field applying step). When the horizontal magnetic field with the convection direction fixing magnetic field intensity K1 (for instance, 0.1 tesla) acts on the silicon melt M through the process in Step S4, the convection of the silicon melt M is fixed counterclockwise to enter the counterclockwise vortex mode.

Next, the controller 23 determines, on the basis of the signal corresponding to the measurement result from the radiation thermometers 15B, whether or not the convection mode of the silicon melt M is fixed to the counterclockwise vortex mode (Step S5: a convection direction confirming step).

In response to determining that the convection mode is not fixed to the counterclockwise vortex mode (Step S5: NO), the controller 23 again performs the process in Step S5 after the elapse of a predetermined duration of time.

In contrast, in response to determining that the convection mode is fixed to the counterclockwise vortex mode (Step S6: YES), the controller 23 controls the pull-up driver 20 to grow the monocrystalline silicon SM while continuing the application of the horizontal magnetic field (Step S6: a growing step). In Step S6, the pull-up driver 20 causes, on the basis of control by the controller 23, the pull-up shaft 7 to move up and down to immerse the seed crystal SC into the silicon melt M and subsequently pull up the seed crystal SC to grow the monocrystalline silicon SM.

### Effects of Exemplary Embodiment

In the monocrystalline silicon manufacturing apparatus 1, the first heat generator 40A to the fourth heat generator 40D of the heater 4 are electrically connected to the power source 94 and at least one of the first support electrode 92A to the fourth support electrode 92D, which support the heater 4, is the high-resistance support electrode 92H.

By configuring the first support electrode 92A to the fourth support electrode 92D in this manner, it is possible to cause the current flowing through the high-resistance support electrode 92H to be smaller than the current flowing through the low-resistance support electrode 92L, enabling the non-uniform heating temperatures of the first heat generator 40A to the fourth heat generator 40D. Thus, it is possible to heat the crucible 3 in the non-uniform heating state, enabling a downward flow of the silicon melt M to occur at a stable position. Therefore, by applying the horizontal magnetic field to the silicon melt M in which the downward flow is occurring at the stable position, it is possible to fix the convection mode of the silicon melt M in a desired state, enabling the manufacturing of the monocrystalline silicon SM with a stable oxygen concentration. Moreover, since the manufacturing of the monocrystalline silicon SM with a stable oxygen concentration is possible, a yield of the monocrystalline silicon SM is increased, allowing for an improvement in energy efficiency and achievement of an increase in production efficiency and a reduction in waste.

Moreover, since it is possible to achieve the non-uniform heating state merely by using the high-resistance support electrode 92H as at least one of the first support electrode 92A to the fourth support electrode 92D, a typical heater 4 is allowed to be used, eliminating the necessity of considerably changing an apparatus configuration.

Further, it is possible to adjust the resistance value of the high-resistance support electrode 92H to be larger by a simple method, merely adjusting the diameter of the small-diameter electrode body 921H, which facilitates the achievement of the desired non-uniform heating state.

### Modifications

Although the exemplary embodiment of the invention is described in detail with reference to the drawings hereinabove, the specific configuration is not limited to this exemplary embodiment and a variety of improvements, design changes, and the like are within the scope of the invention without departing from the gist of the invention.

In a case where a plurality of support electrodes among the first support electrode 92A to the fourth support electrode 92D are provided by the high-resistance support electrodes 92H, the resistance value of at least one of the high-resistance support electrodes 92H may be higher than those of the other high-resistance support electrodes 92H.

The heat insulator 6 may be disposed with the heat insulator center axis 6C being coaxial with the crucible center axis 3C and the heater center axis 4C so that the heat removal distribution with respect to the crucible 3 is uniform.

Although the configuration including the heat insulator 6 with the uniform thermal conductivity throughout is described by way of example, a cylindrical heat insulator having a portion different in thermal conductivity from the other portions may be disposed with a center axis of that heat insulator being coaxial with the crucible center axis 3C and the heater center axis 4C to cause non-uniform heat removal distribution with respect to the crucible 3. In this case, the thermal conductivity of the heat insulator may be set so that Equation (3) above is satisfied or not satisfied.

### EXAMPLES

Next, Examples of the invention will be described. It should be noted that the invention is by no means limited to Examples.

### Experimental Conditions

### Definition of Position of Melt High-Temperature Region

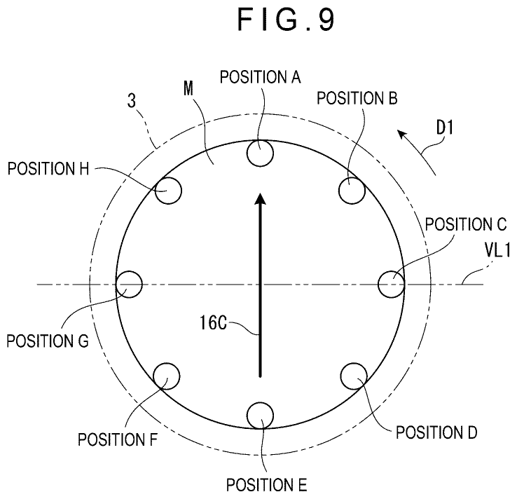

A position A to a position H indicating positions of melt high-temperature regions in plan view are defined as illustrated in FIG. 9. The position A is a position at which an angle made by a reference line extending ahead of the central magnetic field line 16C in the application direction from the center of the silicon melt M and a level line extending from the center of the silicon melt M to the position A in plan view is 0 degrees. The position B, the position C, the position D, the position E, the position F, the position G, and the position H are positions rotated clockwise from the position A by 45 degrees, 90 degrees, 135 degrees, 180 degrees, 225 degrees, 270 degrees, and 315 degrees, respectively.

### Comparative Example

First, the monocrystalline silicon manufacturing apparatus 1 of the above-described exemplary embodiment was prepared.

Then, thicknesses of all the first support electrode 92A to the fourth support electrode 92D were equalized and the heat insulator 6 was disposed with the heat insulator center axis 6C being coaxial with the crucible center axis 3C and the heater center axis 4C.

In a case of Comparative Example, the crucible 3 is heated in the uniform heating state, so that neither the melt high-temperature region nor the melt low-temperature region is generated in the silicon melt M. In other words, a difference in melt temperature is zero degrees C. under the conditions of Comparative Example.

Then, a monocrystalline silicon SM including a straight body SM3 with a diameter of 300 mm and a length of 2000 mm was grown by performing Step S1 to Step S6 of the above-described method of manufacturing the monocrystalline silicon SM. It should be noted that the rotation direction D1 of the crucible 3 is a counterclockwise direction in FIG. 9.

### Examples 1 to 16

In Examples 1 to 8, the heat insulator 6 was disposed with the heat insulator center axis 6C being coaxial with the crucible center axis 3C and the heater center axis 4C. Then, thicknesses of the first support electrode 92A to the fourth support electrode 92D were adjusted so that the melt high-temperature region was located at each of the position A, the position B, the position C, the position D, the position E, the position F, the position G, and the position H and each difference in melt temperature at the positions was 3 degrees C. and a monocrystalline silicon SM was grown under the same conditions as in Comparative Example.

In Examples 9 to 16, a monocrystalline silicon SM was grown under the same conditions as in Examples 1 to 8 except that the position of the heat insulator 6 with respect to the crucible 3 and the heater 4 was adjusted so that the melt high-temperature region was located at each of the position A, the position B, the position C, the position D, the position E, the position F, the position G, and the position H and each difference in melt temperature at the positions was 5 degrees C.

### Evaluations

Before the start of the growth of the monocrystalline silicon SM in Comparative Example and Examples 1 to 16, the horizontal magnetic field was applied at a random timing after the generation of the silicon melt M, a convection mode was observed, and an occurrence rate of each convection mode and a stability of a generated vortex were evaluated.

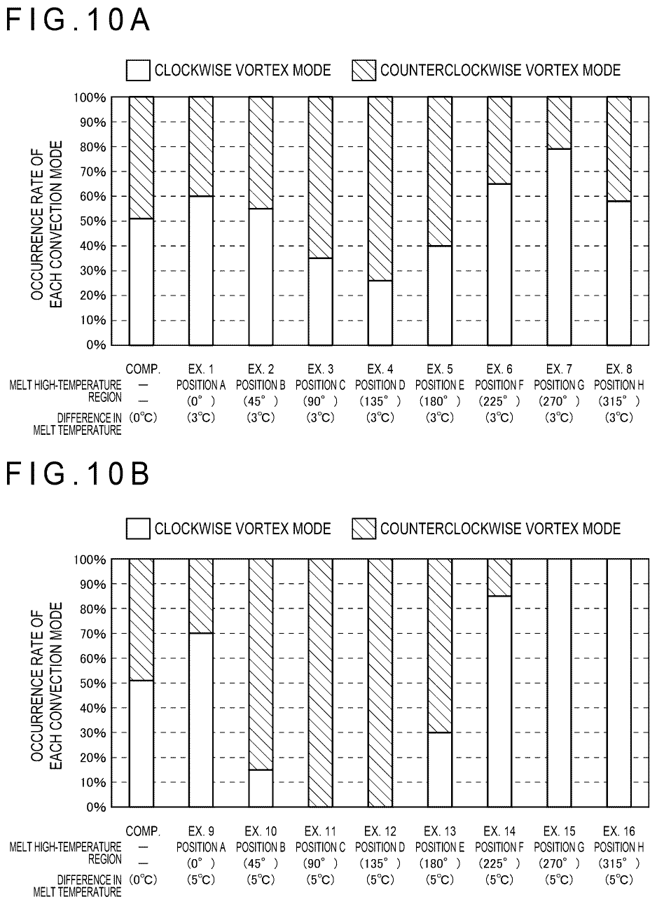

The occurrence rate of each convection mode is shown in Table 1 below and FIG. 10A and FIG. 0B and evaluation results of the stability of vortex are shown in Table 1.

TABLE 1

| | | | Occurrence Rate | | |
|---|---|---|---|---|---|
| | Difference | | of | | |
| | in | | Convection Mode (%) | | |
| | Melt Temp. | Melt High-Temp. | Clockwise | Counterclockwise | Vortex |
| | (° C.) | Portion | Vortex | Vortex | Stability |
| Comp. | 0 | N/A | 51 | 49 | Fair |
| Ex. 1 | 3 | Position A (0°) | 60 | 40 | Fair |
| Ex. 2 | | Position B (45°) | 55 | 45 | Fair |
| Ex. 3 | | Position C (90°) | 35 | 65 | Good |
| Ex. 4 | | Position D (135°) | 26 | 74 | Good |
| Ex. 5 | | Position E (180°) | 40 | 60 | Fair |
| Ex. 6 | | Position F (225°) | 65 | 35 | Good |
| Ex. 7 | | Position G (270°) | 79 | 21 | Good |
| Ex. 8 | | Position H (315°) | 58 | 42 | Good |
| Ex. 9 | 5 | Position A (0°) | 70 | 30 | Good |
| Ex. 10 | | Position B (45°) | 15 | 85 | Good |
| Ex. 11 | | Position C (90°) | 0 | 100 | Good |
| Ex. 12 | | Position D (135°) | 0 | 100 | Excellent |
| Ex. 13 | | Position E (180°) | 30 | 70 | Good |
| Ex. 14 | | Position F (225°) | 85 | 15 | Good |
| Ex. 15 | | Position G (270°) | 100 | 0 | Good |
| Ex. 16 | | Position H (315°) | 100 | 0 | Excellent |

Excellent: No occurrence of inversion of vortex
Good: Infrequent occurrence of inversion of vortex (the probability of inversion being less than 10%)
Fair: Occurrence of inversion of vortex (the probability of inversion being 10% or more)

In Comparative Example, the occurrence rate of the clockwise vortex mode and the occurrence rate of the counterclockwise vortex mode were almost the same, as shown in Table 1 and FIG. 10A and FIG. 10B. Moreover, in Comparative Example, the direction of the vortex having been fixed once inverted with a probability of 10% or more.

A reason for such a result is thought to be that the crucible 3 was heated in the uniform heating state and the position of the downward flow changed at random, so that the clockwise vortex mode or the counterclockwise vortex mode occurred depending on the application timing of the horizontal magnetic field.

In contrast, in Examples 1 to 8, a difference between the occurrence rate of the clockwise vortex mode and the occurrence rate of the counterclockwise vortex mode was 10% or more as shown in Table 1 and FIG. 10A and, accordingly, it has been found that the convection mode is likely to be fixed to one mode irrespective of the application timing of the horizontal magnetic field as compared with in Comparative Example.

A reason for such a result is thought to be that the crucible 3 was heated in the non-uniform heating state and the position of the downward flow was fixed, which enhanced the probability that the convection mode was fixed to one mode irrespective of the application timing of the horizontal magnetic field.

In particular, in Examples 3, 4, 6, and 7, a difference between the occurrence rate of the clockwise vortex mode and the occurrence rate of the counterclockwise vortex mode was 30% or more and, accordingly, it has been found that the convection mode is more likely to be fixed to one mode irrespective of the application timing of the horizontal magnetic field as compared with in Examples 1, 2, 5, and 8. Moreover, the direction of the vortex having been fixed once inverted with a probability of 10% or more in Examples 1, 2, and 5, whereas the probability of the inversion of the direction of the vortex having been fixed once was less than 10% in Examples 3, 4, and 6 to 8.

It has been found from the comparison between Comparative Example and Examples 1 to 8 that it is possible to make the convection mode likely to be fixed to one mode by adjusting, out of the thicknesses of the first support electrode 92A to the fourth support electrode 92D and the location of the heat insulator 6, at least the thicknesses of the first support electrode 92A to the fourth support electrode 92D so that the difference in melt temperature is 3 degrees C. or more, which allows for manufacturing a monocrystalline silicon with a stable oxygen concentration without the necessity of considerably changing a typical apparatus configuration.

Moreover, in Examples 9 to 16, a difference between the occurrence rate of the clockwise vortex mode and the occurrence rate of the counterclockwise vortex mode was 40% or more as shown in Table 1 and FIG. 10B and, accordingly, it has been found that the direction of the convection is more likely to be fixed to one direction irrespective of the application timing of the horizontal magnetic field as compared with in Comparative Example and Examples 1 to 8. Further, in Examples 9 to 16, the probability of the inversion of the direction of the vortex having been fixed once was less than 10%.

A reason for such a result is thought to be that since the difference in melt temperature was larger than those of Examples 1 to 8, a stronger downward flow than those of Examples 1 to 8 was generated and a position of that downward flow was fixed, which further enhanced the probability that the direction of the convection was fixed to one direction irrespective of the application timing of the horizontal magnetic field.

In particular, in Examples 10 to 12 and 14 to 16, the difference between the occurrence rate of the clockwise vortex mode and the occurrence rate of the counterclockwise vortex mode was 70% or more and, accordingly, it has been found that the direction of the convection is further likely to be fixed to one direction irrespective of the application timing of the horizontal magnetic field as compared with in Examples 9 and 13.

A reason for such a result is thought to be that while the melt high-temperature region was located on the central magnetic field line 16C in plan view and thus a downward flow on the opposite side to the melt cooling region with respect to the center of the silicon melt M occurred near the central magnetic field line 16C in Examples 9 and 13, the melt high-temperature region was located on the right or left side with respect to the central magnetic field line 16C in plan view and thus a downward flow occurred in a region away from the central magnetic field line 16C in Examples 10 to 12 and 14 to 16, which further enhanced the probability that the direction of the convection was fixed to one direction irrespective of the application timing of the horizontal magnetic field as compared with in Examples 9 and 13.

Moreover, in Examples 11, 12, 15, and 16, the difference between the occurrence rate of the clockwise vortex mode and the occurrence rate of the counterclockwise vortex mode was 100% and, accordingly, it has been found that the direction of the convection is further likely to be fixed to one direction irrespective of the application timing of the horizontal magnetic field as compared with in Examples 10 and 14.

A reason for such a result is speculated as follows. As described above, the melt high-temperature region rotates in the rotation direction D1 with a rotation of the crucible 3. Moreover, the melt-point high-temperature region of Example 10 was located in front in the rotation direction D1 with respect to the melt-point high-temperature regions of Examples 11 and 12 and the melt-point high-temperature region of Example 14 was located in front in the rotation direction D1 with respect to the melt-point high-temperature regions of Examples 15 and 16. Thus, the positions of the melt-point high-temperature regions when a horizontal magnetic field of 0.1 tesla, which was the convection direction fixing magnetic field intensity K1 in Examples 11, 12, 15, and 16, acted were close to the first horizontal virtual line VL1 as compared with in Examples 10 and 14, which possibly further enhanced the probability that the direction of the convection was fixed to one direction irrespective of the application timing of the horizontal magnetic field.

Moreover, in Examples 12 and 16, no inversion of the direction of the vortex having been fixed once occurred and, accordingly, it has been found that the clockwise vortex mode or the counterclockwise vortex mode is likely to stably occur irrespective of the application timing of the horizontal magnetic field as compared with in Examples 11 and 15.

A reason for such a result is thought to be that since the melt-point high-temperature region of Example 11 was located in front in the rotation direction D1 with respect to the melt-point high-temperature region of Example 12 and the melt-point high-temperature region of Example 15 was located in front in the rotation direction D1 with respect to the melt-point high-temperature region of Example 16, the positions of the melt-point high-temperature regions when a horizontal magnetic field of 0.1 tesla acted in Examples 12 and 16 were close to the first horizontal virtual line VL1 as compared with in Examples 11 and 15, which made the clockwise vortex mode or the counterclockwise vortex mode likely to stably occur irrespective of the application timing of the horizontal magnetic field.

It has been found from the comparison between Examples 1 to 8 and Examples 9 to 16 that it is possible to make the convection mode more likely to be fixed to one mode by adjusting the thicknesses of the first support electrode 92A to the fourth support electrode 92D and the location of the heat insulator 6 so that the difference in melt temperature is 5 degrees C. or more, which allows for manufacturing a monocrystalline silicon with a more stable oxygen concentration without the necessity of considerably changing a typical apparatus configuration.

Incidentally, it is supposed that the use of a cylindrical heat insulator having a portion different in thermal conductivity from the other portions in place of the heat insulator 6 with a uniform thermal conductivity throughout also produces a similar result to those of Examples.

### INDUSTRIAL APPLICABILITY

A method of manufacturing monocrystalline silicon and a monocrystalline silicon manufacturing apparatus according to the invention make it possible to manufacture a monocrystalline silicon with a stable oxygen concentration without the necessity of considerably changing a typical apparatus configuration. Therefore, a yield of the monocrystalline silicon is increased, allowing for an improvement in energy efficiency and achievement of an increase in production efficiency and a reduction in waste.

### EXPLANATION OF CODES

1 . . . monocrystalline silicon manufacturing apparatus, 3 . . . crucible, 3C . . . crucible center axis, 3MA, 3MB . . . maximum heating temperature position, 4 . . . heater, 40A . . . first heat generator, 40B . . . second heat generator, 40C . . . third heat generator, 40D . . . fourth heat generator, 4C . . . heater center axis 6 . . . heat insulator, 6C . . . heat insulator center axis, 92A . . . first support electrode, 92B . . . second support electrode, 92C . . . third support electrode, 92D . . . fourth support electrode, 92H . . . high-resistance support electrode (small-diameter support electrode), 94 . . . power source, M . . . silicon melt, SM . . . monocrystalline silicon, VL1 . . . first horizontal virtual line, VL2, VL3 . . . second horizontal virtual line

1. A method of manufacturing monocrystalline silicon, comprising pulling up a monocrystalline silicon while applying a horizontal magnetic field to a silicon melt, with use of a monocrystalline silicon manufacturing apparatus, wherein
the monocrystalline silicon manufacturing apparatus comprises:
a crucible in which the silicon melt is received;
a heater formed in a cylindrical shape surrounding the crucible, the heater being disposed with a center axis of the cylindrical shape being coaxial with a center axis of the crucible; and
a first support electrode, a second support electrode, a third support electrode, and a fourth support electrode each formed in a rod shape from a material with electrical conductive properties and supporting the heater,
the heater comprising a first heat generator, a second heat generator, a third heat generator, and a fourth heat generator each having identical heat generation characteristics and being arranged in an outer peripheral direction of the crucible,
the first support electrode connecting the first heat generator and the second heat generator to a positive electrode of a power source,
the second support electrode connecting the second heat generator and the third heat generator to a negative electrode of the power source or a ground,
the third support electrode connecting the third heat generator and the fourth heat generator to the positive electrode,
the fourth support electrode connecting the fourth heat generator and the first heat generator to the negative electrode or the ground,
at least one of the first support electrode, the second support electrode, the third support electrode, or the fourth support electrode being a small-diameter support electrode having at least a portion that is smaller in thickness than remaining ones of the first to fourth support electrodes,
the method further comprising:
generating the silicon melt by heating a silicon material in the rotating crucible while a heat generation distribution of the heater is non-uniform;
starting applying the horizontal magnetic field to the silicon melt; and
growing the monocrystalline silicon by pulling up a seed crystal immersed in the silicon melt after a convection direction of the silicon melt in a virtual plane perpendicular to a central magnetic field line of the horizontal magnetic field is fixed to one direction.

2. The method of manufacturing monocrystalline silicon according to claim 1, wherein the monocrystalline silicon manufacturing apparatus comprises a heat insulator formed in a cylindrical shape surrounding the heater, the heat insulator being configured to provide a non-uniform heat removal distribution with respect to the heater.

3. The method of manufacturing monocrystalline silicon according to claim 2, wherein the heat insulator has uniform thermal conductivity throughout and is disposed with a center axis of the heat insulator not being coaxial with the center axis of the crucible.

4. The method of manufacturing monocrystalline silicon according to claim 2, wherein the heat insulator is configured such that the thermal conductivity of one portion differs from that of other portions and is disposed with a center axis of the heat insulator being coaxial with the center axis of the crucible.

5. The method of manufacturing monocrystalline silicon according to claim 2, wherein
when a rotation speed of the crucible during application of the horizontal magnetic field to the silicon melt is defined as R (rpm), and a time elapsed from the start of the application of the horizontal magnetic field until the horizontal magnetic field with a magnetic field intensity sufficient to fix the convection direction acts on the silicon melt is defined as T (minute),
the first support electrode, the second support electrode, the third support electrode, the fourth support electrode, and the heat insulator are configured such that: a maximum heating temperature position at which a heating temperature applied to the crucible is highest in plan view is located on a side opposite to a rotation direction of the crucible with respect to a first horizontal virtual line, the first horizontal virtual line being perpendicular to the central magnetic field line and including the center axis of the crucible; and an angle θ (degree) made by a second horizontal virtual line and the first horizontal virtual line satisfies Equation (1) below, the second horizontal virtual line connecting the center axis of the crucible and the maximum heating temperature position,
$$θ = 360 \times R \times T . \qquad ( 1 )$$

6. A monocrystalline silicon manufacturing apparatus configured to pull up monocrystalline silicon while applying a horizontal magnetic field to a silicon melt, the monocrystalline silicon manufacturing apparatus comprising:
a crucible in which the silicon melt is received;
a heater formed in a cylindrical shape surrounding the crucible, the heater being disposed with a center axis of the cylindrical shape being coaxial with a center axis of the crucible; and
a first support electrode, a second support electrode, a third support electrode, and a fourth support electrode each formed in a rod shape from a material with electrical conductive properties and supporting the heater, wherein
the heater comprises a first heat generator, a second heat generator, a third heat generator, and a fourth heat generator each having identical heat generation characteristics and being arranged in an outer peripheral direction of the crucible,
the first support electrode connects the first heat generator and the second heat generator to a positive electrode of a power source,
the second support electrode connects the second heat generator and the third heat generator to a negative electrode of the power source or a ground,
the third support electrode connects the third heat generator and the fourth heat generator to the positive electrode,
the fourth support electrode connects the fourth heat generator and the first heat generator to the negative electrode or the ground, and
at least one of the first support electrode, the second support electrode, the third support electrode, or the fourth support electrode is a small-diameter support electrode having at least a portion that is smaller in thickness than remaining ones of the first to fourth support electrodes.

7. The monocrystalline silicon manufacturing apparatus according to claim 6, further comprising:
a heat insulator formed in a cylindrical shape surrounding the heater, the heat insulator being configured to provide a non-uniform heat removal distribution with respect to the heater.

8. The monocrystalline silicon manufacturing apparatus according to claim 7, wherein the heat insulator has uniform thermal conductivity throughout and is disposed with a center axis of the heat insulator not being coaxial with the center axis of the crucible.

9. The monocrystalline silicon manufacturing apparatus according to claim 7, wherein the heat insulator is configured such that thermal conductivity of one portion differs from that of other portions and is disposed with a center axis of the heat insulator being coaxial with the center axis of the crucible.

10. The monocrystalline silicon manufacturing apparatus according to claim 7,
when a rotation speed of the crucible during application of the horizontal magnetic field to the silicon melt is defined as R (rpm), and a time elapsed from the start of the application of the horizontal magnetic field until the horizontal magnetic field with a magnetic field intensity sufficient to fix a convection direction acts on the silicon melt is defined as T (minute),
the first support electrode, the second support electrode, the third support electrode, the fourth support electrode, and the heat insulator are configured such that: a maximum heating temperature position at which a heating temperature applied to the crucible is highest in plan view is located on a side opposite to a rotation direction of the crucible with respect to a first horizontal virtual line, the first horizontal virtual line being perpendicular to the central magnetic field line of the horizontal magnetic field and including the center axis of the crucible; and an angle θ (degree) made by a second horizontal virtual line and the first horizontal virtual line satisfies Equation (2) below, the second horizontal virtual line connecting the center axis of the crucible and the maximum heating temperature position,
$$θ = 360 \times R \times T . \qquad ( 2 )$$

11. The method of manufacturing monocrystalline silicon according to claim 3, wherein
when a rotation speed of the crucible during application of the horizontal magnetic field to the silicon melt is defined as R (rpm), and a time elapsed from the start of the application of the horizontal magnetic field until the horizontal magnetic field with a magnetic field intensity sufficient to fix the convection direction acts on the silicon melt is defined as T (minute),
the first support electrode, the second support electrode, the third support electrode, the fourth support electrode, and the heat insulator are configured such that: a maximum heating temperature position at which a heating temperature applied to the crucible is highest in plan view is located on a side opposite to a rotation direction of the crucible with respect to a first horizontal virtual line, the first horizontal virtual line being perpendicular to the central magnetic field line and including the center axis of the crucible; and an angle θ (degree) made by a second horizontal virtual line and the first horizontal virtual line satisfies Equation (1) below, the second horizontal virtual line connecting the center axis of the crucible and the maximum heating temperature position,
$$θ = 360 \times R \times T . \qquad ( 1 )$$

12. The method of manufacturing monocrystalline silicon according to claim 4, wherein
when a rotation speed of the crucible during application of the horizontal magnetic field to the silicon melt is defined as R (rpm), and a time elapsed from the start of the application of the horizontal magnetic field until the horizontal magnetic field with a magnetic field intensity sufficient to fix the convection direction acts on the silicon melt is defined as T (minute),
the first support electrode, the second support electrode, the third support electrode, the fourth support electrode, and the heat insulator are configured such that: a maximum heating temperature position at which a heating temperature applied to the crucible is highest in plan view is located on a side opposite to a rotation direction of the crucible with respect to a first horizontal virtual line, the first horizontal virtual line being perpendicular to the central magnetic field line and including the center axis of the crucible; and an angle θ (degree) made by a second horizontal virtual line and the first horizontal virtual line satisfies Equation (1) below, the second horizontal virtual line connecting the center axis of the crucible and the maximum heating temperature position,
$$θ = 360 \times R \times T . \qquad ( 1 )$$

13. The monocrystalline silicon manufacturing apparatus according to claim 8,
when a rotation speed of the crucible during application of the horizontal magnetic field to the silicon melt is defined as R (rpm), and a time elapsed from the start of the application of the horizontal magnetic field until the horizontal magnetic field with a magnetic field intensity sufficient to fix a convection direction acts on the silicon melt is defined as T (minute),
the first support electrode, the second support electrode, the third support electrode, the fourth support electrode, and the heat insulator are configured such that: a maximum heating temperature position at which a heating temperature applied to the crucible is highest in plan view is located on a side opposite to a rotation direction of the crucible with respect to a first horizontal virtual line, the first horizontal virtual line being perpendicular to the central magnetic field line of the horizontal magnetic field and including the center axis of the crucible; and an angle θ (degree) made by a second horizontal virtual line and the first horizontal virtual line satisfies Equation (2) below, the second horizontal virtual line connecting the center axis of the crucible and the maximum heating temperature position,
$$θ = 360 \times R \times T . \qquad ( 2 )$$

14. The monocrystalline silicon manufacturing apparatus according to claim 9,
when a rotation speed of the crucible during application of the horizontal magnetic field to the silicon melt is defined as R (rpm), and a time elapsed from the start of the application of the horizontal magnetic field until the horizontal magnetic field with a magnetic field intensity sufficient to fix a convection direction acts on the silicon melt is defined as T (minute),
the first support electrode, the second support electrode, the third support electrode, the fourth support electrode, and the heat insulator are configured such that: a maximum heating temperature position at which a heating temperature applied to the crucible is highest in plan view is located on a side opposite to a rotation direction of the crucible with respect to a first horizontal virtual line, the first horizontal virtual line being perpendicular to the central magnetic field line of the horizontal magnetic field and including the center axis of the crucible; and an angle θ (degree) made by a second horizontal virtual line and the first horizontal virtual line satisfies Equation (2) below, the second horizontal virtual line connecting the center axis of the crucible and the maximum heating temperature position,
$$θ = 360 \times R \times T . \qquad ( 2 )$$
